(19) United States
(12) Patent Application Publication
(10) Pub. No.: US 2010/0182037 A1
(43) Pub. Date: Jul. 22, 2010

(54) Diagnostic Method For Load-Testing Self-Excited Three-Phase Generators in a Motor Vehicle

(75) Inventors: Hermann Bosch, Esslingen (DE); Matthias Kronewitter, Esslingen (DE); Dietmar Munz, Kernen (DE); Stefan Weis, Wolfschlugen (DE)

Correspondence Address: CROWELL & MORING LLP;INTELLECTUAL PROPERTY GROUP, P.O. BOX 14300, WASHINGTON, DC, 20044-4300, US

(73) Assignee: Daimler AG, Stuttgart (DE)

(21) Appl. No.: 11/995,395

(22) PCT Filed: Jul. 1, 2006
(86) PCT No.: PCT/EP06/06412

§ 371 Date: Mar. 25, 2010

(30) Foreign Application Priority Data
Jul. 14, 2005 (DE) 10 2005 032 923.3

(51) Int. Cl. G01R 31/34

(52) U.S. Cl. 324/772

(57) ABSTRACT

The invention relates to a diagnostic method for self-excited generators, in which a diagnostic decision is made by means of field current monitoring.

### CROSS REFERENCE TO RELATED APPLICATIONS

This application is a continuation of PCT International Application No. PCT/EP2006/006412, filed Jul. 1, 2006, which claims priority under 35 U.S.C. §119 to German Patent Application No. 10 2005 032 923.3, filed Jul. 14, 2005, the entire disclosures of which are herein expressly incorporated by reference.

### BACKGROUND AND SUMMARY OF THE INVENTION

The invention relates to a diagnostic method for three-phase generators with self-excitation. The method can be applied in a motor vehicle in which generators supply sufficient current in an onboard vehicle power system.

The invention is based on an onboard vehicle power system on which diagnostics can be performed, such as is disclosed for example in German laid-open patent application DE 102 58 899 A1. With a power management system which is implemented in a microcontroller it is possible to measure and sense the currents of loads in the onboard vehicle power system using control devices and sensors which are installed in them. These currents, which actually occur in individual loads or in individual branches of the onboard vehicle power system, are compared by the power management system with the setpoint currents which are expected in the present system state and are calculated from the system state. The setpoint currents constitute limiting values of tolerance ranges at which upward transgression diagnostics can be carried out by the power management system using stored fault scenarios, and if appropriate the actions which are necessary for the individual fault situation are initiated. These actions are carried out using control instructions to the control devices which are connected to the power management system or switching elements which can be actuated. The communications interfaces to the units which are involved in the power management system can be achieved using a simple serial interface, parallel interfaces, or complex bus interfaces based on the CAN (Controlled Area Network) technology, the LIN (Local Interconnect Network) technology, the SI (Safety and Information bus system) bus technology or the TTP (Time Triggered Protocol) technology.

With the abovementioned methods, which operate on the basis of the monitoring of current with upward transgression of a limiting value, only current branches and loads in an onboard vehicle power system can be monitored. The generator cannot be monitored in this way. The reason for this lies in the control system with which the output voltage of the generator is adjusted to a predefined value. Possible defects of the generator are compensated in this control system by subsequent adjustment of the self-excitation of the generator. Faults in the generator can be suspected only if the subsequent adjustment no longer brings about the voltage level which is to be set at the generator terminals. However, in the installed state under load an onboard vehicle power system overload due to defective loads can still be responsible for the excessively low terminal voltage.

It has previously been possible to determine whether a generator has its full performance only by manual measurement of the generator current with an external measuring device at a predefined rotational speed of the driven internal combustion engine. However, this entails increasing uncertainties in modern vehicles in which generator management functions are being increasingly used. In fact, measurement of the current at the time of an intended, limited generator power level leads to an incorrect diagnosis here. Furthermore, in some cases it is no longer possible to carry out measurement of the generator current manually in the installed state. When there are problems in the onboard vehicle power system this means that the generator is often considered to be a cause for the onboard vehicle power system problems and is replaced even though the generator does not have a fault.

Exemplary embodiments of the invention provide techniques for diagnostics of the performance of a generator with self-excitation.

These techniques include a diagnostic method in which the present exciter current of the generator is compared with an expected exciter current.

The solution is achieved by monitoring the exciter current of self-excited three-phase generators. The logic interface of three-phase generators indicates, inter alia, the present exciter current which, given a constant rotational speed, is relatively proportional to the generator power tapped at the onboard vehicle power system. By comparing the present exciter current with an exciter current which is expected according to the system state a diagnostic decision is made.

In one advantageous embodiment, the generator load is increased by predefining a defined and known load jump in the onboard vehicle power system. The present increase in the exciter current is then compared with an expected increase in the exciter current and a diagnostic decision is derived therefrom.

Owing to the change in the exciter current it is possible to determine, in both exemplary embodiments, whether a generator with reduced maximum power is present. In the case of a defective generator, which is no longer capable of providing its maximum power, a higher exciter current will result in the case of a defective generator than is expected in the case of an intact generator.

The advantages which can be achieved mainly therewith are the capability of diagnosing the generator in the installed state via a logic diagnostic interface without having to perform a manual measurement of current for this purpose. The removal of an intact generator can be prevented and a generator with reduced power can be identified through logic driving using the workshop diagnostics or the power management system.

Other objects, advantages and novel features of the present invention will become apparent from the following detailed description of the invention when considered in conjunction with the accompanying drawings.

### BRIEF DESCRIPTION OF THE DRAWING FIGURES

The invention will be explained in more detail below by means of graphic illustrations, in which:

FIG. 1 shows a typical onboard vehicle power system with a self-excited three-phase generator and logic interface and connected loads which can also be actuated via logic interfaces, and

FIG. 2 shows voltage and exciter current diagrams when there is a load jump in the onboard vehicle power system.

### DETAILED DESCRIPTION

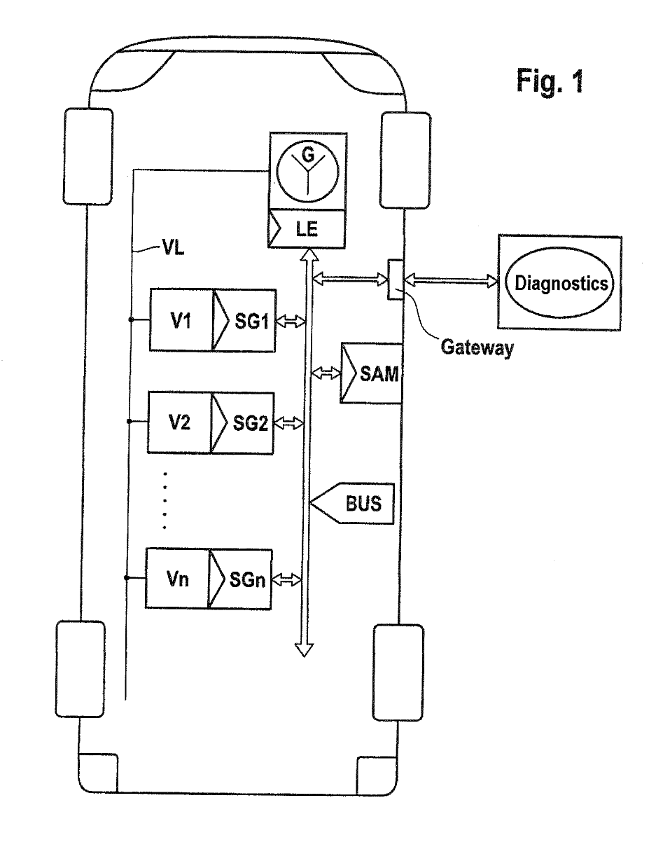

FIG. 1 shows an onboard vehicle power system which is known per se in a motor vehicle. The connected loads V1, V2, . . . , Vn are supplied with electrical energy using a generator G which is usually driven by the internal combustion engine of the motor vehicle. The individual loads are controlled by control devices SG1, SG2, . . . , SGn which are assigned to the loads either indirectly or directly. The individual control devices are connected using a communications network, such as a bus, both to one another and to an onboard vehicle power system control device, referred to as a SAM (Signal and Actuation Module) in a communication-transmitting fashion. The power electronics LE and the generator control of the onboard vehicle power system generator are also connected to the communications network with a logic interface. Furthermore, the communications network has a further interface for the connection of external diagnostic systems. This interface can be formed using the diagnostic socket in relatively old vehicles or can be embodied as a gateway when bus technologies are used if the diagnostic system and the vehicle-internal onboard vehicle power system use different communication protocols. If the same communication system as in the vehicle is used by the diagnostic system, a gateway can be dispensed with and only a simple bus interface is required.

In at least one of the control devices which is installed in the motor vehicle, such as in the onboard vehicle power system control device, a power management system is implemented with which the energy which is discharged from the generator into the onboard vehicle power system is distributed among the connected loads. The present invention is based on the power management system which is implemented as control software in one of the control devices in the onboard vehicle power system of the motor vehicle.

Contemporary onboard vehicle power system generators with self-excitation have a logic interface which is often embodied as a LIN bus interface. These generators have therefore often also been referred to as LIN generators. The operating parameters of the generator can also be read via this logic interface during the operation of the generator, and it is possible to influence the control of the generator using control instructions. As a result, what are referred to as generator management functions, which can be implemented in the power management system, can be set up. One of the most important manipulated variables for the discharge of power by the generator is in this context the exciter current whose present value is therefore also made available as a bus message via the logic interface of these generators and can be further processed by the power management system.

This permits an onboard vehicle power system generator to be diagnosed using an onboard power management system or an external workshop diagnostic system according to the following method. Given the same motor speed of the internal combustion engine and of the onboard vehicle power system generator, the exciter current of the onboard vehicle power system generator is determined for a defined and known load state of the generator and is compared with the calculated value, expected according to the load state, of an intact generator for this load state. If a generator with, for example, a diode fault is present, this generator can compensate its performance which is reduced by a fault below its maximum load by increasing the exciter current. If the exciter current which is determined for a known load state is therefore above the expected exciter current, this is an indication of a defect or a malfunction of the generator. The generator currents which are expected for a known load state can usually be determined from the load exciter-current characteristic diagram lines of the installed generator.

In a motor vehicle it may, under certain circumstances, be difficult to determine the load state by sensing all the load states. This applies in particular if no power management system is implemented in the onboard vehicle power system or not all loads are actuated via the power management system. In this case, the onboard vehicle power system generator can be diagnosed using an alternative method. By connecting a defined load with a precisely known power consumption it is possible to generate a load jump when there is a constant or at least identical generator rotational speed in the onboard vehicle power system. The generator control system will then react with an increase in the exciter current. Owing to the known increase in load, an increased exciter current which is to be expected for intact generators can be calculated or read out from a load exciter-current characteristic diagram and compared with the actual exciter current after the load jump. For a defective generator, the exciter current which occurs after the load jump will be higher than the expected exciter current. An unexpectedly high exciter current after the applied load jump can be evaluated by a power management system or by a diagnostic system as an indication of a defective generator.

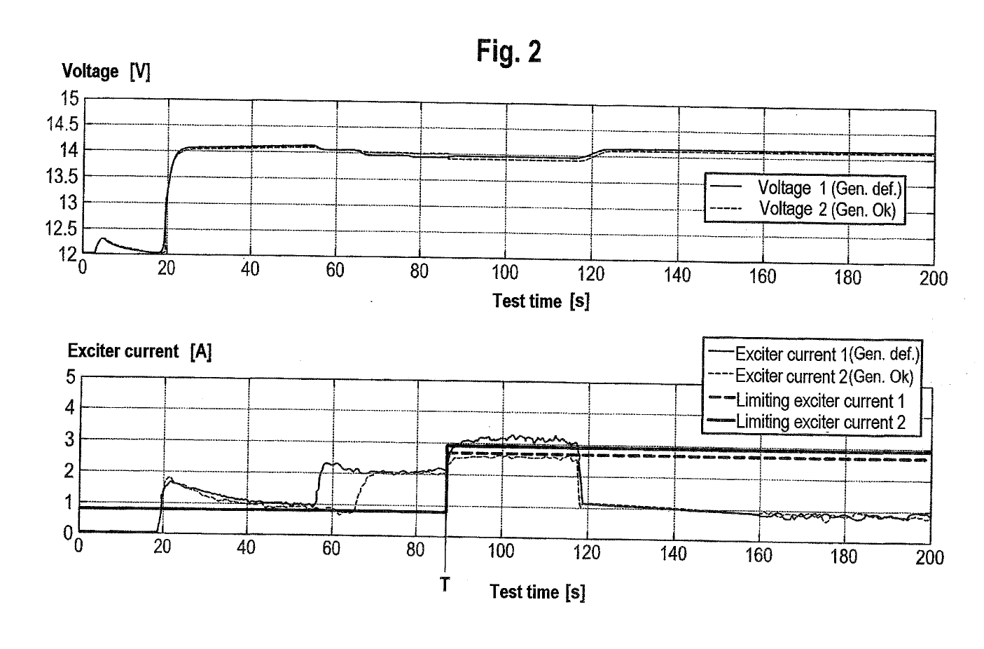

The exemplary embodiment with an applied load jump is represented in the voltage and exciter current diagrams in FIG. 2. The generator voltage is plotted against the time and the exciter current against the time. In the voltage diagram, the generator voltages of an intact generator are plotted with a broken line and the generator voltage of a defective generator is plotted with a continuous line. It is apparent that owing to the control behavior of the generator control system at the voltage position a defective generator cannot be distinguished from an intact one. This is the case at least until the generator is not adjusted to its maximum power. The control system compensates a power defect by increasing the exciter voltage. In the selected exemplary embodiment according to FIG. 2, the generator load is adjusted to an average capacity utilization state of the generator after approximately 60 seconds. This state of the generator capacity utilization is particularly helpful for diagnostics since here the saturation of the exciter field increases and as a result an unexpected increase in the exciter current of a possibly defective generator becomes particularly apparent.

At the time T, that is to say after approximately 85 seconds after the start of the diagnostics given the selected test protocol, a defined load jump is applied to the generator and the expected exciter current of an intact generator for said load jump is determined. This expected exciter current is represented in the diagram with a broken line and is referred to by limiting exciter current 1. In order to avoid evaluation problems owing to the ripple of the exciter current, this expected limiting value will advantageously be increased by an empirical value, preferably by the order of magnitude of this ripple, for the purpose of the diagnostics, and this combined value will then be adopted as a comparison value for making the diagnostic decision. The expected exciter current which has been increased by the empirical value is illustrated in the diagram in FIG. 2 by a continuous line and is referred to by limiting exciter current 2.

A defective generator is detected if the actual exciter current is above the expected exciter current or also above the expected exciter current which is increased by the ripple of the exciter current. The exciter current profile of an intact generator is shown by a wavy, broken line. The exciter current profile of a defective generator is shown by a continuous, wavy line. It is apparent that during the applied load jump the actual exciter current of the defective generator is above both expected limiting values for the exciter current of an intact generator.

The diagnostic function can be implemented in all embodiment variants both onboard in the power management system and offboard in an external diagnostic system with comparison of the expected exciter current and the actual exciter current for a known load or for an applied load jump.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1-6. (canceled)

7. A diagnostic method for load-testing self-excited three-phase generators in a motor vehicle, the method comprising:
comparing a present exciter current of the generator with an expected exciter current; and
detecting whether the generator is defective based on the comparison.

8. The diagnostic method as claimed in claim 7, further comprising:
applying a load jump to the generator, wherein the present exciter current is compared with the exciter current which is expected as a result of the load jump after application of the load jump.

9. The diagnostic method as claimed in claim 7, wherein an empirical value is added to the expected exciter current.

10. The diagnostic method as claimed in claim 8, wherein an empirical value is added to the expected exciter current.

11. The diagnostic method as claimed in claim 9, wherein the empirical value corresponds essentially to the fluctuation range of the exciter current.

12. The diagnostic method as claimed in claim 10, wherein the empirical value corresponds essentially to the fluctuation range of the exciter current.

13. The diagnostic method as claimed in claim 7, wherein the method is carried out onboard in the motor vehicle.

14. The diagnostic method as claimed in claim 7, wherein the method is carried out offboard with a diagnostic system.
